(19) United States
(12) Patent Application Publication
(10) Pub. No.: US 2005/0007737 A1
(43) Pub. Date: Jan. 13, 2005

(54) Power supply used for desknote

(76) Inventor: Chun Chen Chen, Taoyuan Hsien (TW)

Correspondence Address: MADSON & METCALF;GATEWAY TOWER WEST, SUITE 900, 15 WEST SOUTH TEMPLE, SALT LAKE CITY, UT, 84101, US

(21) Appl. No.: 10/756,233

(22) Filed: Jan. 13, 2004

(30) Foreign Application Priority Data
Jul. 9, 2003 (TW) 92118779

(51) Int. Cl. H05K 7/20

(52) U.S. Cl. 361/690; 361/692

(57) ABSTRACT

A power supply used for a desknote is disclosed. The power supply used for a desknote includes a casing, an air inlet located on a first side surface of the casing, an air outlet located on a second side surface opposite to the first side surface, an output element located on the first side surface or the second side surface, and an input element located on the second side surface or the first side surface opposite to the output element. By the arrangement of the output element and the input element, the air inlet and the air outlet are not covered by objects other than the casing to prevent the airflow from being blocked.

### FIELD OF THE INVENTION

This invention relates to a power supply, and more particularly to a power supply used for a desknote.

### BACKGROUND OF THE INVENTION

With the needs of consumers and the development trend of electronic products, desktops are gradually eliminated and substituted by notebooks, which have smaller sizes. However, due to the limitation of the size, many electronic components, such as the disk driver, can not be installed in the host of the computer. Therefore, by the current technology, a desknote with the size between the sizes of the desktop and the notebook is developed. This new desknote has a moderate size, so that it can be installed many electronic components, and is also easy to carry. Certainly, the electronic apparatuses equipped with the desknote are different from the convention electronic apparatuses. Taking the power supply as an example, the power supply used for the conventional desktop is installed in the host of the computer, but the power supply used for the desknote is an independent electronic apparatus which is not installed in the host of the computer, and its size is between the sizes of the power supplies used for the conventional desktop and the notebook.

Generally speaking, the power supply installed in the conventional desktop is usually equipped with a fan for heat-dissipating. However, when the power supply is removed from the host, the heat-dissipating problem thereof would be the key point for whether the computer can be normally operated. Please refer to FIG. 1 which is a schematic view showing the power supply used for a desknote according to the prior art. As shown in FIG. 1, the power supply includes a casing 11, an output element 12 and an input element 13, in which the casing has an air inlet 111 and an air outlet 112. By the airflow through the air inlet and the air outlet, the heat generated from the power supply can be dissipated. However, since this kind of power supply is not installed in the host of the computer, the air inlet and the air outlet sometimes are unintentionally covered or blocked by other objects or walls. In this situation, the air can not freely flow through the air inlet and the air outlet, so that the heat of the power supply can not be dissipated, and thus the power supply and also the desknote can not be normally operated. Furthermore, if the heat can not be dissipated efficiently, the electronic elements in the power supply would be damaged easily, which decreases the life span of the power supply and increases the breakdown rate of the desknote.

Therefore, it is needed to provide a power supply used for the desknote which can overcome the disadvantages of the prior art as described above.

### SUMMARY OF THE INVENTION

It is an object of the present invention to provide a power supply used for a desknote which employs the arrangement of the output element and the input element and/or the shape change of the side surface of the casing to keep the free airflow through the air inlet and the air outlet and dissipate the heat generated from the power supply, so as to overcome the heat-dissipating problem of the power supply.

In accordance with an aspect of the present invention, the power supply used for a desknote includes a casing, an air inlet located on a first side surface of the casing, an air outlet located on a second side surface opposite to the first side surface, an output element located on the first side surface or the second side surface, and an input element located on the second side surface or the first side surface opposite to the output element. By the arrangement of the output element and the input element, the air inlet and the air outlet are not covered by objects other than the casing to prevent the airflow from being blocked.

Preferably, the output element and/or the input element are selected from the group consisting of a plug, a socket and a power cord.

Preferably, the air inlet and/or the air outlet include plural air vents.

Preferably, the air inlet and/or the air outlet are formed integrally with the casing.

Preferably, the casing has plural air vents disposed on any the surface of the casing.

Preferably, the casing has a heat-dissipating fan therein at the location of the air inlet or the air outlet.

In accordance with another aspect of the present invention, the power supply used for a desknote includes a casing, an air inlet located on a first side surface of the casing, and an air outlet located on a second side surface opposite to the first side surface. At least one of the first side surface and the second side surface is a non-vertical plane, so that the air inlet and the air outlet are not covered by objects other than the casing to prevent the airflow from being blocked.

Preferably, the non-vertical plane is one selected from the group consisting of an arc plane, a pyramid plane, a wave plane and a slant plane.

Preferably, the power supply further includes an output element and/or an input element.

Preferably, the output element and/or the input element are selected from the group consisting of a plug, a socket and a power cord.

Preferably, the air inlet and/or the air outlet include plural air vents.

Preferably, the air inlet and/or the air outlet are formed integrally with the casing.

Preferably, the casing has plural air vents disposed on any the surface of the casing.

Preferably, the casing has a heat-dissipating fan therein at the location of the air inlet or the air outlet.

In accordance with another aspect of the present invention, the power supply used for a desknote includes a casing, an air inlet located on a first side surface of the casing, an air outlet located on a second side surface opposite to the first side surface, wherein at least one of the first side surface and the second side surface has a concave portion at the location of the air inlet or the air outlet, and an output element and/or and an input element located on the first side surface and/or the second side surface. Thereby, the air inlet and the air outlet are not covered by objects other than the casing to prevent the airflow from being blocked.

Preferably, the output element and/or the input element are selected from the group consisting of a plug, a socket and a power cord.

Preferably, the air inlet and/or the air outlet include plural air vents.

Preferably, the air inlet and/or the air outlet are formed integrally with the casing.

Preferably, the casing has plural air vents disposed on any the surface of the casing.

Preferably, the casing has a heat-dissipating fan therein at the location of the air inlet or the air outlet.

The above objects and advantages of the present invention will become more readily apparent to those ordinarily skilled in the art after reviewing the following detailed description and accompanying drawings, in which:

### BRIEF DESCRIPTION OF THE DRAWINGS

FIG. 1 is a schematic view showing the power supply used for a desknote according to the prior art;

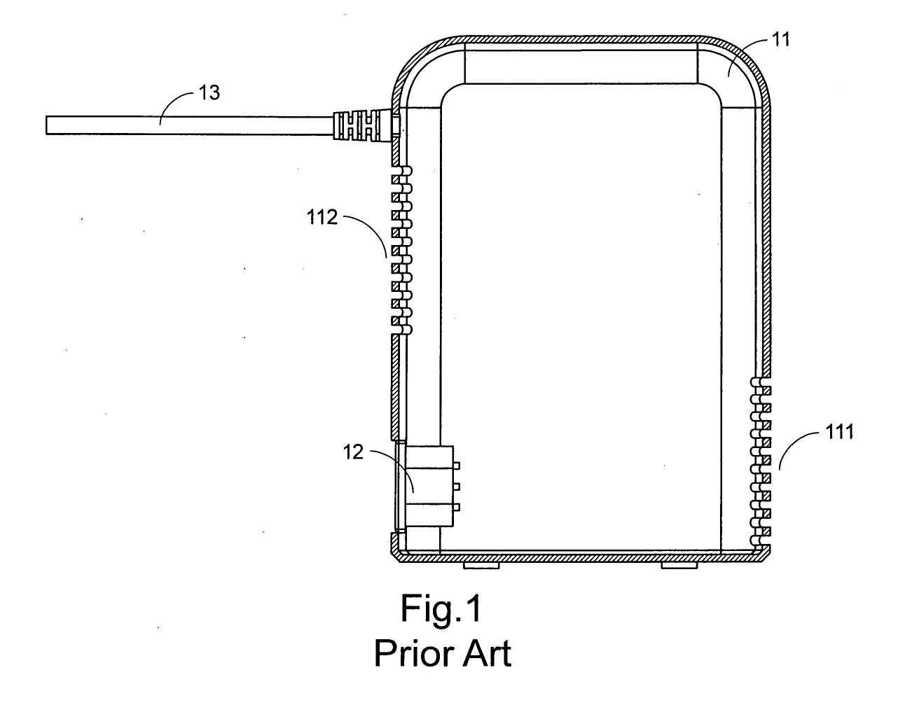

FIG. 2 is a schematic view showing the power supply according to the first preferred embodiment of the present invention;

FIG. 3 which is a schematic view showing the power supply according to the second preferred embodiment of the present invention; and

FIG. 4 which is a schematic view showing the power supply according to the third preferred embodiment of the present invention

### DETAILED DESCRIPTION OF THE PREFERRED EMBODIMENT

The present invention relates to a power supply used for a desknote which combines the advantages of the desktop and the notebook. It is characterized in that the power supply used for the desknote is not installed in the host of the computer as that of the conventional desktop is, and its size is between the sizes of the power supplies used for the conventional desktop and the notebook.

The power supply used for a desknote of the present invention mainly includes a casing, an air inlet, an air outlet, an output element and an input element, in which the air inlet and the air outlet are located on two opposite side surfaces of the casing. By the arrangement of the output element and the input element or the design of the casing, the air inlet and the air outlet would not be covered by objects other than the casing, so as to prevent the airflow from being blocked and increase the heat-dissipating efficiency of the power supply. In the embodiments of the present invention, the input element and the output element are variably and cooperatively selected from the group consisting of a plug, a socket and a power cord. For the convenience of description, the following embodiments are illustrated with a power supply having a socket as the input element and a power cord as the output element, in which the socket can be connected to a plug of a power cord for inputting the commercially available power, and the power supply can output the power to the desknote via the output element of the power cord.

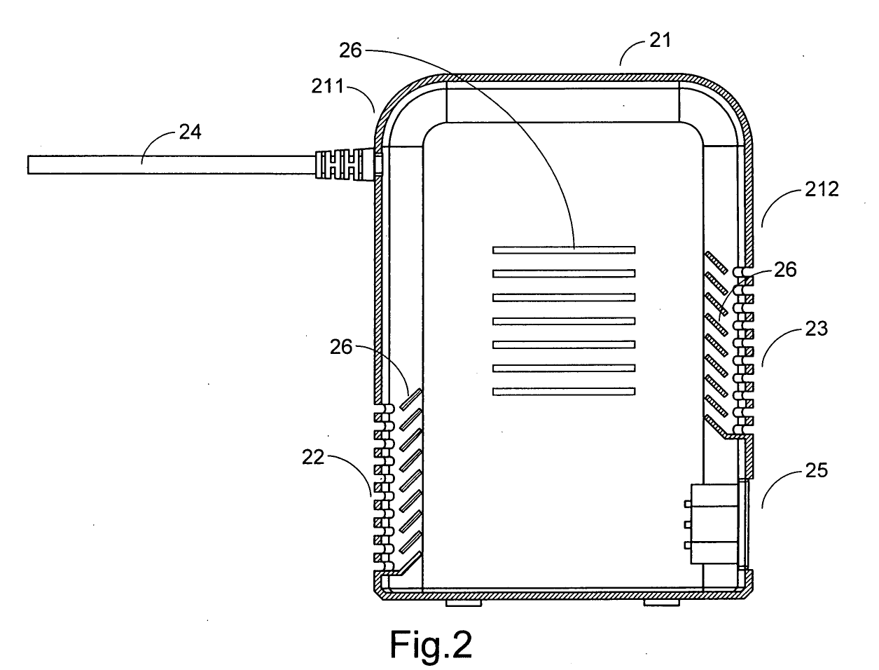

Please refer to FIG. 2 which is a schematic view showing the power supply according to the first preferred embodiment of the present invention. As shown in FIG. 2, the power supply used for a desknote at least includes a casing 21, an air inlet 22, an air outlet 23, a power cord 24 and a socket 25. The air inlet 22 is located on a first side surface 211 of the casing 21, and the air outlet 23 is located on the second side surface 212 opposite to the first side surface 211. In addition, the power cord 24 is located on the first side surface 211, and the socket 25 is located on the second side surface 212 (certainly, they can be interchanged). Since the socket 25 needs connecting with a plug of a power cord for inputting the commercially available power, and the power cord 24 needs connecting to the desknote, when the power supply is being used, even though the power supply is unintentionally moved to the corner by the user and contacts to other objects, such as walls or boards of the desks (not shown), the first side surface 211 and the second side surface 212 would not be completely covered by those objects, i.e. the air inlet 22 and the air outlet 23 would not be sealed, so that the airflow would not be blocked and the heat of the power supply can be dissipated. Therefore, the user do not have to worried about the problems of unstable operating system or crash which is easily caused due to the overhigh temperature of the power supply. Moreover, the air inlet 22 and the air outlet 23 can further include plural air vents 26 in shutter form, and the casing can also include plural air vents 26 in shutter form, which can be disposed on any side surface of the casing 21, so as to increase the heat-dissipating efficiency of the power supply.

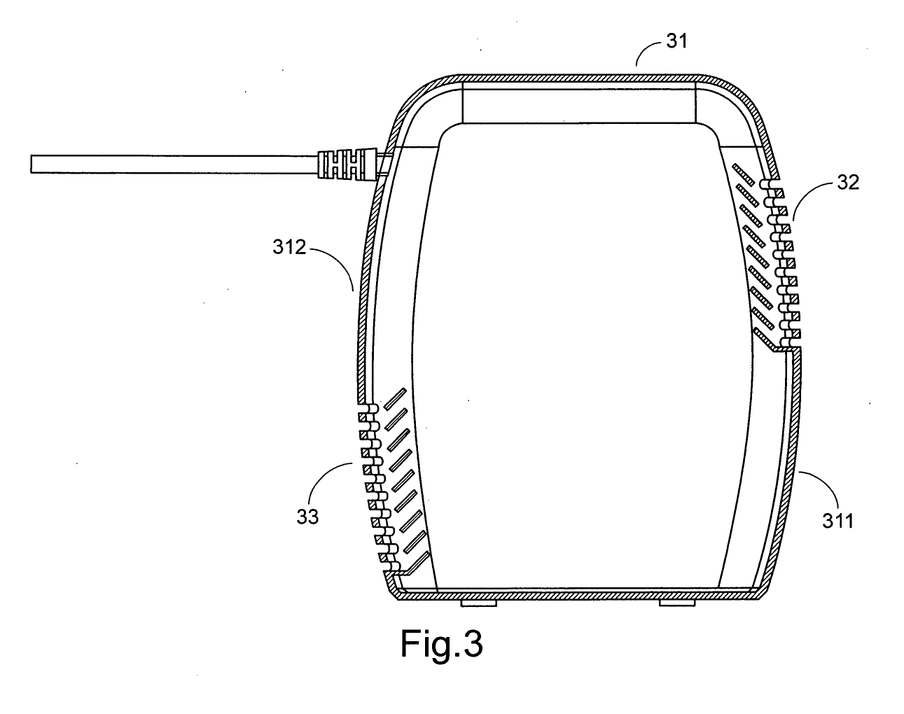

Please refer to FIG. 3 which is a schematic view showing the power supply according to the second preferred embodiment of the present invention. As shown in FIG. 3, the power supply used for a desknote at least includes a casing 31, an air inlet 32, and an air outlet 33. The air inlet 32 is located on a first side surface 311 of the casing 31, and the air outlet 33 is located on the second side surface 312 opposite to the first side surface 311. The first side surface 311 and the second side surface 312 are arc planes, and certainly can also be pyramid planes, wave planes or slant planes. When the power supply is unintentionally moved to the walls or the boards of the desks (not shown), the first side surface 311 and the second side surface 312, which are arc planes, would not be completely covered by the walls or the boards of the desks, so that the airflow through the air inlet 32 and the air outlet 33 would not be blocked and the heat of the power supply can be dissipated.

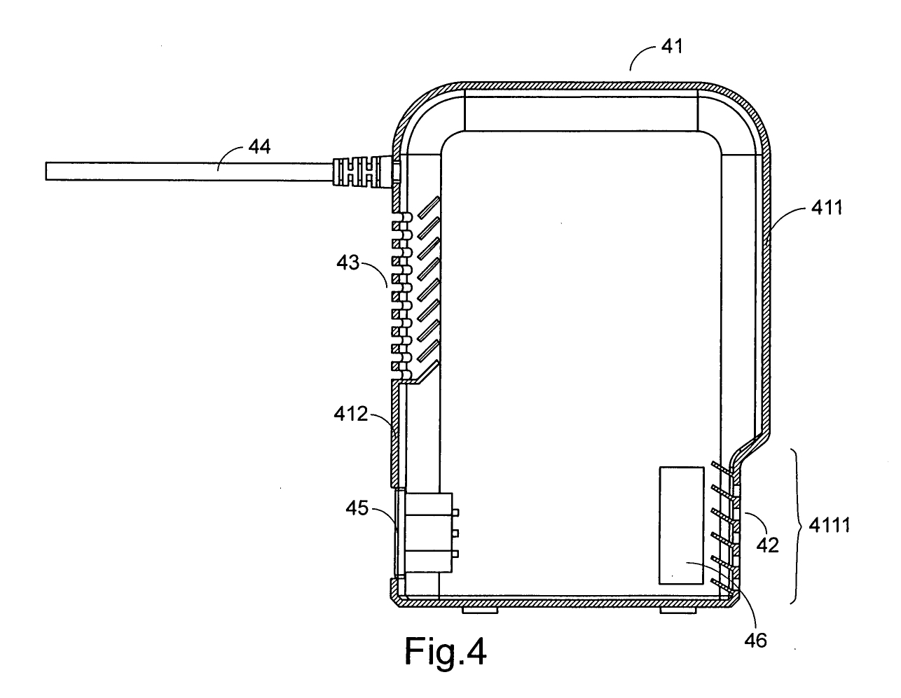

Please refer to FIG. 4 which is a schematic view showing the power supply according to the third preferred embodiment of the present invention. As shown in FIG. 4, the power supply used for a desknote at least includes a casing 41, an air inlet 42, and an air outlet 43. The air inlet 42 is located on a first side surface 411 of the casing 41, and the air outlet 43 is located on the second side surface 412 opposite to the first side surface 411. At least the first side surface 411 has a concave portion 4111 at the location of the air inlet 42, and the power cord 44 and the socket 45 are located on the second side surface 412. When the power supply is unintentionally moved to the walls or the boards of the desks (not shown), the concave portion 4111 of the first side surface 411 can keep the free airflow through the air inlet 42, and the power cord 44 and the socket 45 can keep the free airflow through the air outlet 43, so that the heat of the power supply can be dissipated.

In the foregoing first, second and third embodiments, the power supply used for the desknote of the present invention can further include a heat-dissipating fan 46 (as shown in FIG. 4) installed in the casing near the location of the air inlet or the air outlet, so as to increase the speed of the airflow and further increase the heat-dissipating efficiency of the power supply. In addition, the air inlet and the air outlet can be formed integrally with the casing of the power supply, or can be formed by pressing. Moreover, the air inlet, air outlet, output element, input element, and the shape of the side surface of the casing can be variably designed to cooperate with each other to keep the free airflow through the air inlet and the air outlet.

In conclusion, the power supply of the present invention employs the arrangement of the output element and the input element and/or the shape change of the side surface of the casing to prevent the air inlet and the air outlet from being covered by other objects, so as to keep the free airflow through the air inlet and the air outlet and dissipate the heat generated from the power supply when it is used, so that the defects resulted from the overhigh temperature of the power supply can be avoided. In addition, the power supply used for the desknote of the present invention can further include a heat-dissipating fan installed in the casing to increase the heat-dissipating efficiency. Moreover, the air inlet and/or the air outlet can be formed integrally with the casing in the manufacturing process, so the manufacturing cost and time would not be increased. Therefore, the present invention overcomes the disadvantages of the prior art and possesses the industrial value.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

1. A power supply used for a desknote, comprising:
a casing;
an air inlet located on a first side surface of said casing;
an air outlet located on a second side surface opposite to said first side surface;
an output element located on said first side surface or said second side surface; and
an input element located on said second side surface or said first side surface opposite to said output element;
wherein by the arrangement of said output element and said input element, said air inlet and said air outlet are not covered by objects other than said casing to prevent the airflow from being blocked.

2. The power supply according to claim 1 wherein said output element and/or said input element are selected from the group consisting of a plug, a socket and a power cord.

3. The power supply according to claim 1 wherein said air inlet and/or said air outlet comprise plural air vents.

4. The power supply according to claim 1 wherein said air inlet and/or said air outlet are formed integrally with said casing.

5. The power supply according to claim 1 wherein said casing has plural air vents disposed on any said surface of said casing.

6. The power supply according to claim 1 wherein said casing has a heat-dissipating fan therein at the location of said air inlet or said air outlet.

7. A power supply used for a desknote, comprising:
a casing;
an air inlet located on a first side surface of said casing; and
an air outlet located on a second side surface opposite to said first side surface;
wherein at least one of said first side surface and said second side surface is a non-vertical plane, so that said air inlet and said air outlet are not covered by objects other than said casing to prevent the airflow from being blocked.

8. The power supply according to claim 7 wherein said non-vertical plane is one selected from the group consisting of an arc plane, a pyramid plane, a wave plane and a slant plane.

9. The power supply according to claim 7 further comprising an output element and/or an input element.

10. The power supply according to claim 9 wherein said output element and/or said input element are selected from the group consisting of a plug, a socket and a power cord.

11. The power supply according to claim 7 wherein said air inlet and/or said air outlet comprise plural air vents.

12. The power supply according to claim 7 wherein said air inlet and/or said air outlet are formed integrally with said casing.

13. The power supply according to claim 7 wherein said casing has plural air vents disposed on any said surface of said casing.

14. The power supply according to claim 7 wherein said casing has a heat-dissipating fan therein at the location of said air inlet or said air outlet.

15. A power supply used for a desknote, comprising:
a casing;
an air inlet located on a first side surface of said casing;
an air outlet located on a second side surface opposite to said first side surface, wherein at least one of said first side surface and said second side surface has a concave portion at the location of said air inlet or said air outlet; and
an output element and/or and an input element located on said first side surface and/or said second side surface;
thereby said air inlet and said air outlet are not covered by objects other than said casing to prevent the airflow from being blocked.

16. The power supply according to claim 15 wherein said output element and/or said input element are selected from the group consisting of a plug, a socket and a power cord.

17. The power supply according to claim 15 wherein said air inlet and/or said air outlet comprise plural air vents.

18. The power supply according to claim 15 wherein said air inlet and/or said air outlet are formed integrally with said casing.

19. The power supply according to claim 15 wherein said casing has plural air vents disposed on any said surface of said casing.

20. The power supply according to claim 15 wherein said casing has a heat-dissipating fan therein at the location of said air inlet or said air outlet.
